(19) United States
(12) Patent Application Publication
(10) Pub. No.: US 2009/0278189 A1
(43) Pub. Date: Nov. 12, 2009

(54) SEMICONDUCTOR DEVICE WITH RESISTOR AND METHOD OF FABRICATING SAME

(75) Inventors: Hoo-Sung CHO, Yongin-si (KR); Kyoung-Hoon KIM, Yongin-si (KR); Nok-Hyun JU, Seoul (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: Samsung Electronics Co., Ltd., Suwon-si (KR)

(21) Appl. No.: 12/434,718

(22) Filed: May 4, 2009

(30) Foreign Application Priority Data
May 8, 2008 (KR) 10-2008-0043007

(51) Int. Cl. H01L 27/06; H01L 29/788

(52) U.S. Cl. 257/316; 257/379; 257/536; 257/E29.3; 257/E27.016

(57) ABSTRACT

A semiconductor device includes a cell array region disposed on a semiconductor substrate and comprising a first cell gate pattern, a cell semiconductor pattern disposed on the first cell gate pattern, and a second cell gate pattern disposed on the cell semiconductor pattern. The semiconductor device also includes a peripheral circuit region disposed on the semiconductor substrate and comprising a peripheral gate pattern, and a resistor disposed in the peripheral circuit region at level above the semiconductor substrate similar to that of the cell semiconductor pattern.

### PRIORITY STATEMENT

This U.S. non-provisional patent application claims priority under 35 U.S.C § 119 to Korean Patent Application 10-2008-0043007 filed on May 8, 2008, the subject matter of which is hereby incorporated by reference.

### BACKGROUND

The present invention relates to semiconductor devices and methods of fabricating same. More specifically, the present invention is directed to a semiconductor device including a resistor and a method of fabricating same.

Modern electronic appliances such as television sets, telephones, and radio sets and computers employ semiconductor devices which are implemented using a great number of electrical components such as transistors, capacitors, diodes, resistors and so forth. Resistors of various types play an important role in operation of nearly every electronic circuit. Unfortunately, resistors tend to vary in size with their resistance value and non-uniform critical dimensions often result from conventional implementations of certain resistors having relatively high resistance.

### SUMMARY

Embodiments of the invention variously provide semiconductor devices, related methods of fabrication, and electronic systems incorporating said semiconductor devices.

In one embodiment, the invention provides a semiconductor device comprising; a cell array region disposed on a semiconductor substrate and comprising a first cell gate pattern, a cell semiconductor pattern disposed on the first cell gate pattern, and a second cell gate pattern disposed on the cell semiconductor pattern, a peripheral circuit region disposed on the semiconductor substrate and comprising a peripheral gate pattern, and a resistor disposed in the peripheral circuit region at level above the semiconductor substrate similar to that of the cell semiconductor pattern.

In another embodiment, the invention provides a method of fabricating a semiconductor device, comprising; stacking second gate pattern on a first gate pattern in a cell array region of a first semiconductor substrate, wherein the second gate pattern is disposed on a cell semiconductor pattern formed on the first semiconductor substrate in the cell array region, forming a peripheral semiconductor pattern on the first semiconductor substrate in a peripheral circuit region, wherein the peripheral semiconductor pattern is formed at the same level above the first semiconductor substrate as the cell semiconductor pattern, and patterning the peripheral semiconductor pattern to form a resistor.

### BRIEF DESCRIPTION OF THE DRAWINGS

FIG. 1 is a cross-sectional view of a semiconductor device with a resistor according to a first embodiment of the present invention.

FIGS. 2A through 2F are cross-sectional views illustrating a method of fabricating the semiconductor device according to the first embodiment of the present invention.

FIG. 3 is a cross-sectional view of a semiconductor device according to a second embodiment of the present invention.

FIG. 4A through 4D are cross-sectional views illustrating a method of fabricating the semiconductor device according to the second embodiment of the present invention.

FIG. 5 is a cross-sectional view of a semiconductor device according to a third embodiment of the present invention.

FIGS. 6A through 6D are cross-sectional views illustrating a method of fabricating the semiconductor device according to the third embodiment of the present invention.

FIG. 7 is a cross-sectional view of a semiconductor device according to a fourth embodiment of the present invention.

FIGS. 8A through 8D are cross-sectional views illustrating a method of fabricating the semiconductor device according to the fourth embodiment of the present invention.

FIG. 9 is a block diagram of an electrical system with a semiconductor device according to embodiments of the present invention.

### DESCRIPTION OF EMBODIMENTS

Embodiments of the invention will now be described in some additional details with reference to the accompanying drawings. The invention may, however, be embodied in many different forms and should not be construed as being limited to only the illustrated embodiments. Rather, these embodiments are presented as teaching examples.

In the drawings, the relative thickness and size of a particular layer or region may be exaggerated for clarity. It will also be understood that when a layer is said to be formed or disposed “on” another layer or substrate, it may be formed or disposed directly on the other layer or substrate, or intervening layers may be present. Throughout the drawings and written description, like numbers refer to like or similar elements.

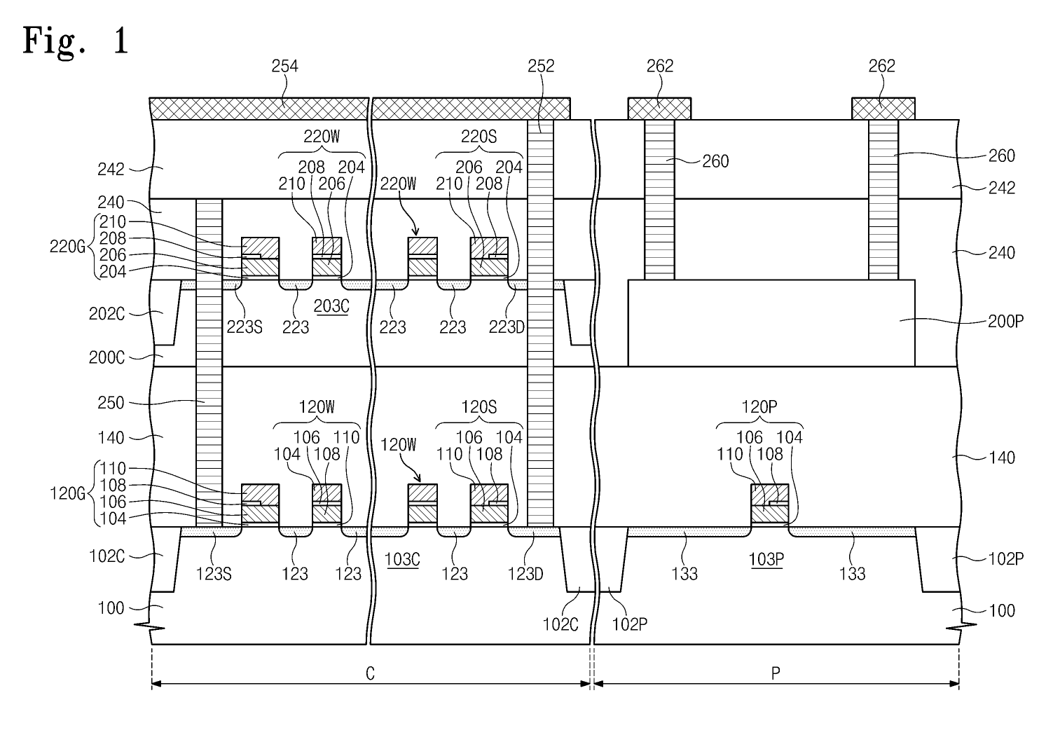

FIG. 1 is a cross-sectional view of a semiconductor device incorporating a resistor according to a first embodiment of the invention. The semiconductor device includes a semiconductor substrate 100 including a cell array region “C” and a peripheral circuit region “P”. The semiconductor substrate 100 may be, for example, a silicon substrate.

A first cell isolation layer 102C is disposed in a semiconductor substrate 100 of the cell array region “C” to define a first cell active region 103C. First cell gate patterns 120S, 120W, and 120G are disposed on the first cell active region 103C. In one embodiment of the invention, the first cell gate patterns 120S, 120W, and 120G may form gate patterns for a NAND flash memory device. The first cell gate patterns 120S, 120W, and 120G may include a first wordline 120W, a first string selection line 120S, and a first ground selection line 120G crossing the first cell active region 103C and the first cell isolation layer 102C. Each of the lines 120W, 120S, and 120G may include a first gate insulating pattern 104, a first floating gate pattern 106, a first gate interlayer dielectric pattern 108, and a first control gate pattern 110 that are stacked in the order named. The first floating gate pattern 106 and the first control gate pattern 110 of the first wordline 120W are separated by the first gate interlayer dielectric pattern 108. On the other hand, the first floating gate pattern 106 and the first control gate pattern 110 of the first string selection line 120S and the first floating gate pattern 106 and the first control gate pattern 110 of the first ground selection line 120G are electrically connected via a butting contact.

First cell conductive regions 123S, 123, and 123D are disposed between first cell gate patterns 120S, 120W, and 120G. An impurity region between the first cell isolation layer 102C and the first string selection line 120S may serve as a first drain region 123D, and an impurity region between the first ground selection line 120G and the first cell isolation layer 102C may serve as a first common source region 123S.

A peripheral isolation layer 102P is disposed in a semiconductor substrate 100 of the peripheral circuit region “P” to define a peripheral active region 103P. A peripheral gate pattern 120P is disposed on the peripheral active region 103P, and a peripheral conductive region 133 may be disposed in the semiconductor substrate 100 adjacent to opposite sides of the peripheral gate pattern 120P. The peripheral gate pattern 120P may include a first gate insulating pattern 104, a first floating gate pattern 106, a first gate interlayer dielectric pattern 108, and a first control gate pattern 110 that are stacked in the order named. The first floating gate pattern 106 and the first control gate pattern 110 of the peripheral gate pattern 120P are electrically connected through a butting contact.

A first interlayer dielectric 140 is disposed to cover the first cell gate patterns 120S, 120W, and 120G and the peripheral gate pattern 120P. A cell semiconductor pattern 200C is disposed on the first interlayer dielectric 140 in the cell array region “C”.

The cell semiconductor pattern 200C may be formed from, for example, a single-crystalline silicon pattern and include the small amount of P-type impurities. A second cell isolation layer 202C is disposed in the cell semiconductor pattern 200C to define a second cell active region 203C. Second cell gate patterns 220S, 220W, and 220G are disposed on the second cell active region 203C. The second cell gate patterns 220S, 220W, and 220G may form gate patterns for a NAND flash memory device in one embodiment of the invention. The second cell gate patterns 220S, 220W, and 220G may include a second wordline 220W, a second string selection line 220S, and a second ground selection line 220G that cross the second cell active region 203C and the second cell isolation layer 202C. Each of the second wordline 220W, the second string selection line 220S, and the ground selection line 220G may include a second gate insulating pattern 204, a second floating gate pattern 206, and a second gate interlayer dielectric pattern 208, and a second control gate pattern 210 that are stacked in the order named. The second gate interlayer dielectric pattern 208 may include oxide-nitride-oxide (ONO). Each of the second floating gate pattern 206 and the second control gate pattern 210 may include polysilicon. The second floating gate pattern 206 and the second control gate pattern 210 of the second wordline 220W are electrically separated by the second gate interlayer dielectric pattern 208. On the other hand, the second floating gate pattern 206 and the second control gate pattern 210 of the second string selection line 220S and the second floating gate pattern 206 and the second control gate pattern 210 of the second ground selection line 220G are electrically connected via a butting contact. Second cell conductive regions 223S, 223, and 223D are formed between the second cell gate patterns 220S, 220W, and 220G. An impurity region between the second string selection line 220S and the second cell isolation layer 202C may be a second drain region 223D, and an impurity region between the second cell isolation layer 202C and the second ground selection line 220G may be a second ground source region 223S.

A peripheral semiconductor pattern 200P is disposed on the first interlayer dielectric 140 in the peripheral circuit region “P”. The peripheral semiconductor pattern 200P may have the same thickness as the cell semiconductor pattern 200C. That is, an upper surface of the peripheral semiconductor pattern 200P may assume the same level as an upper surface of the cell semiconductor pattern 200C. However, peripheral semiconductor pattern 200P may have a smaller width than the cell semiconductor pattern 200C.

In various embodiments of the invention, the peripheral semiconductor pattern 200P may be used as a resistor. The peripheral semiconductor pattern 200P may be fabricated from a similar or different material than the cell semiconductor pattern 200C. For example, the peripheral semiconductor pattern 200P may be formed from a single-crystalline silicon pattern or a polysilicon pattern.

According to the illustrated first embodiment of the invention, the peripheral semiconductor pattern 200P may include a relatively small amount of impurities (e.g., an amount similar to that of the cell semiconductor pattern 200C) or no additionally doped impurities. With such very low impurity concentrations, the peripheral semiconductor pattern 200P will exhibit a relatively high resistive characteristic and may be used to implement a resistor having relatively high resistance.

This approach to the fabrication of a resistor within a semiconductor device makes it possible to avoid several conventional disadvantages, such as non-uniformity in the critical dimension (CD) dispersion of resistor(s) having relatively high resistance. As a result, a resistor may be fabricated with a uniformly defined CD dispersion during a semiconductor fabrication process to yield a semiconductor device having a stable resistance dispersion. Moreover, in certain embodiments of the invention wherein the resistor is fabricated using a peripheral semiconductor pattern 200P formed from the same material as the cell semiconductor pattern 200C on which a memory cell array is formed, overall semiconductor fabrication costs may be reduced.

According to the illustrated first embodiment of the invention, the peripheral semiconductor pattern 200P may be disposed on the peripheral gate pattern 120P in the peripheral circuit region “P” in parallel with the cell semiconductor pattern 200C. Thus, a resulting chip size for the semiconductor device incorporating said resistor may be reduced, as compared with conventionally fabricated semiconductor devices that use a resistive material disposed in a specified a resist region (not shown) or disposed on the peripheral isolation layer 102P of the peripheral circuit region “P”. Often, the resist region is remote from the peripheral gate pattern 120P, but may be included in the peripheral circuit region.

A semiconductor device according to certain embodiments of the invention may be a NAND flash memory device having a multi-layer structure, as illustrated in FIG. 1. Alternately or additionally, the semiconductor device may include circuitry implementing a NOR flash memory device or an SRAM. In the semiconductor device, memory cell arrays of the semiconductor substrate 100 being a first layer and the cell semiconductor pattern 200C being a second layer may be structured variously and independently. For example, a NAND flash memory including a NAND string and a NOR flash memory may be disposed on the semiconductor substrate 100 and the cell semiconductor pattern 200C, respectively and vice versa. Further, an SRAM and a flash memory may be disposed on the semiconductor substrate 100 and the cell semiconductor pattern 200C, respectively and vice versa.

A second interlayer dielectric 240 is disposed to cover the second cell gate patterns 220S, 220W, and 220G and the peripheral semiconductor pattern 200P. A source line contact 250 is disposed through the second interlayer dielectric 240, the cell semiconductor pattern 200C, and the first interlayer dielectric 140 to electrically connect the second common source region 223S to the first common source region 123S. A third interlayer dielectric 242 is disposed on the second interlayer dielectric 240 including the source contact 250.

Resist contacts 260 are electrically connected to the peripheral semiconductor pattern 200P through the second and third interlayer dielectric 240 and 242. Resist interconnections 262 are disposed on the third interlayer dielectric 242 to be electrically connected to the resist contacts 260. A bitline contact 252 may be in electrical contact with the second drain region 223D and the first drain region 123D. A bitline 254 is disposed on the second interlayer dielectric 240 to be electrically connected to the bitline contact 252.

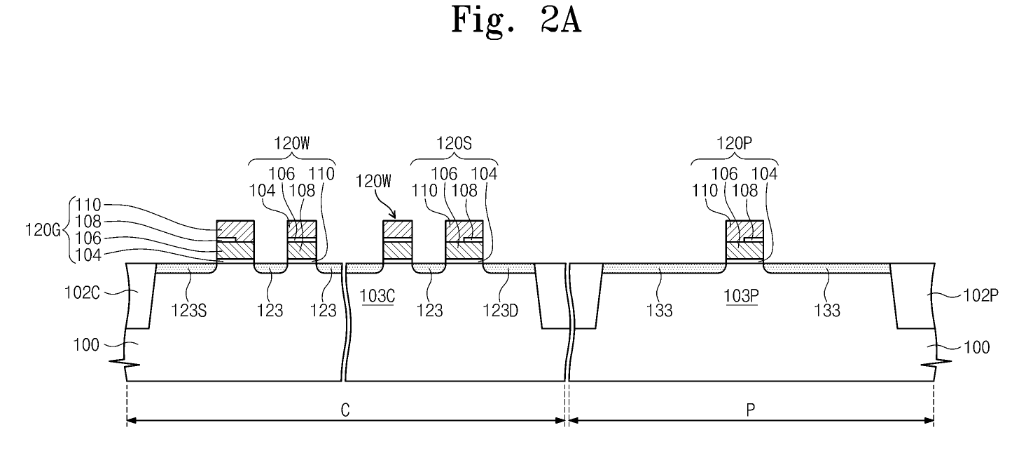

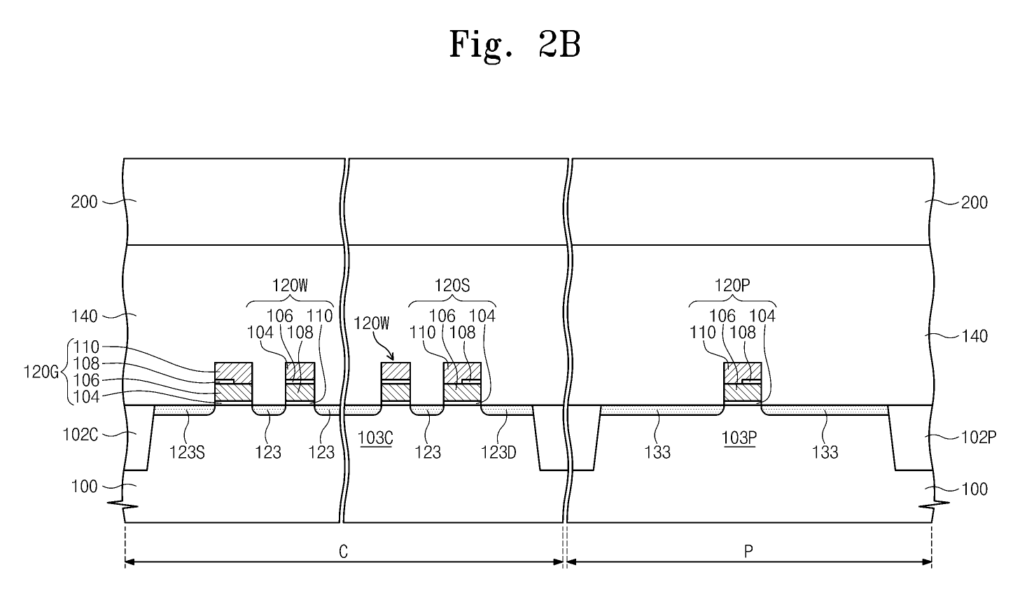

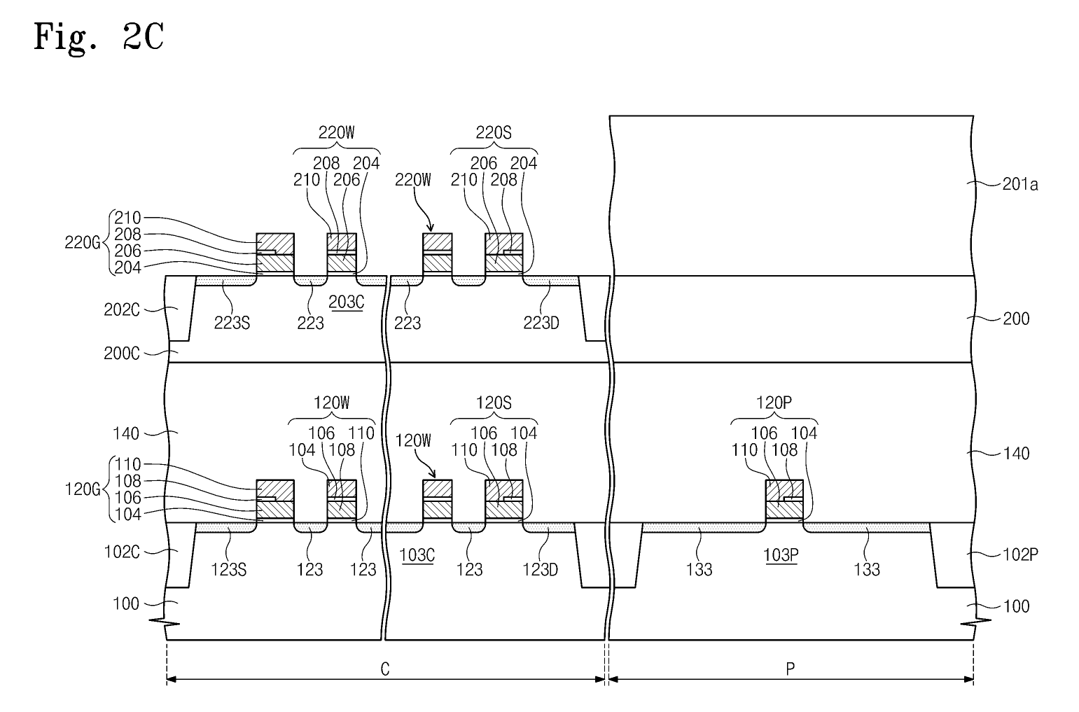

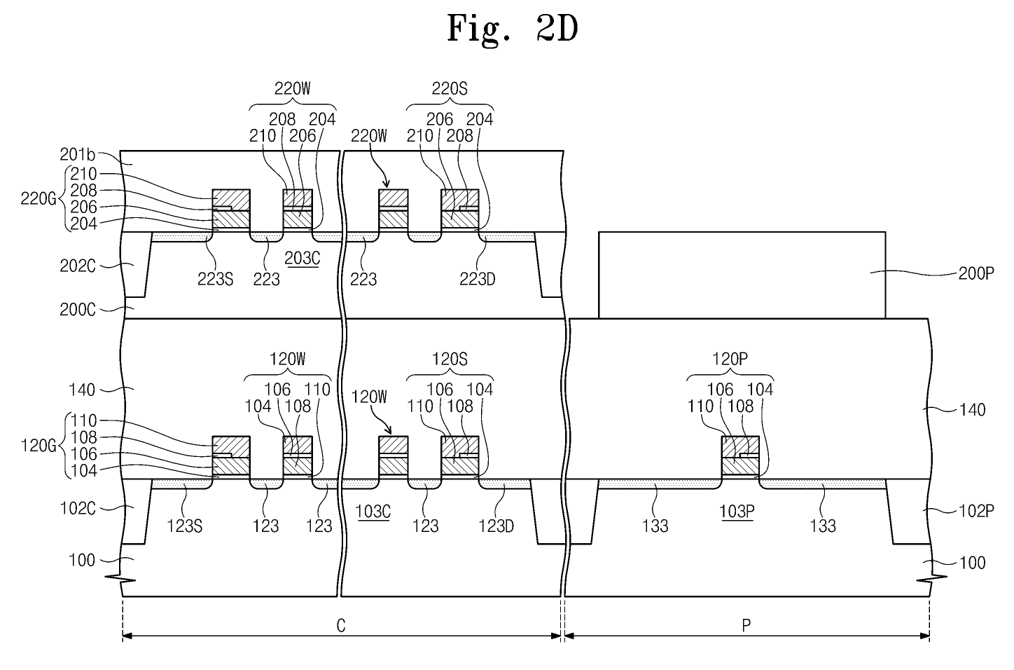

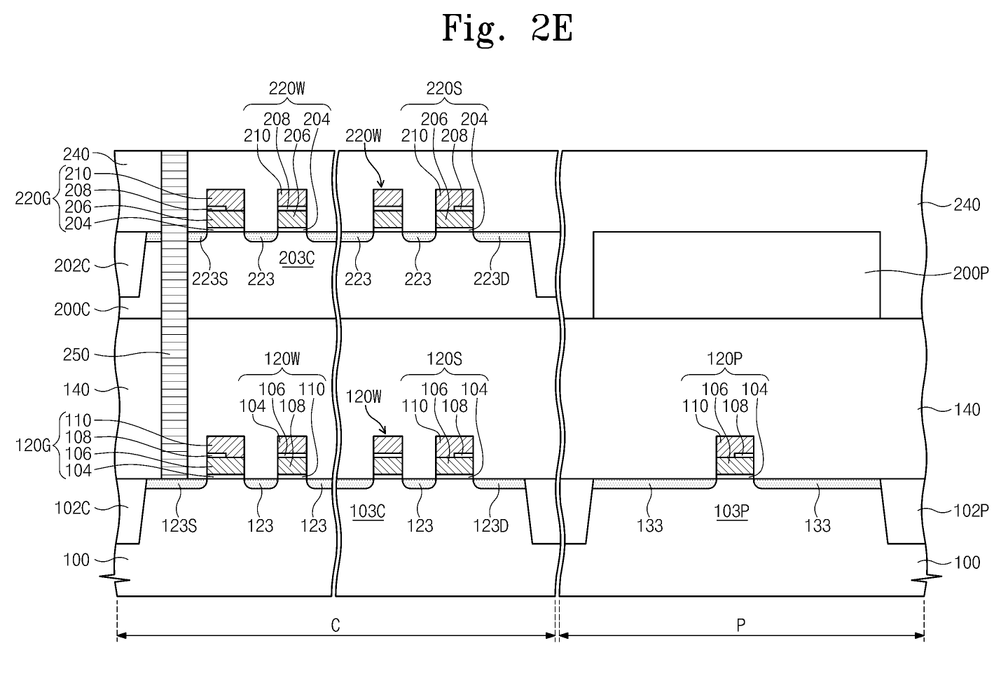

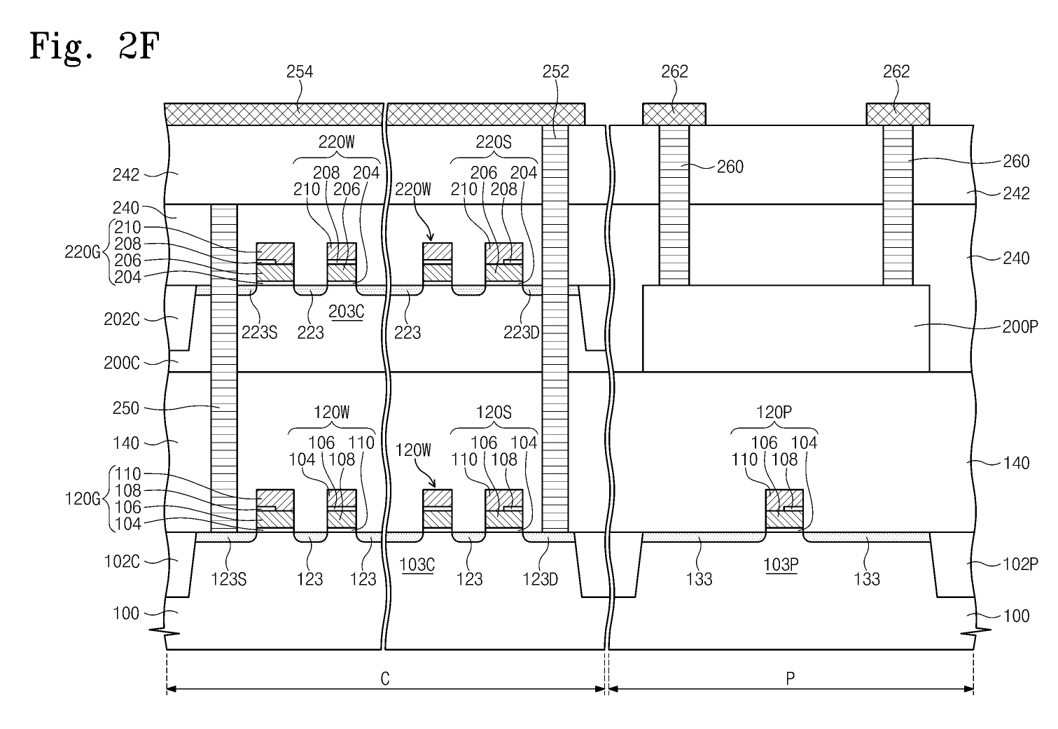

FIGS. 2A through 2E are cross-sectional views illustrating a method of forming a semiconductor device according to the first embodiment of the present invention.

Referring to FIG. 2A, a first semiconductor substrate 100 is provided, including a cell array region “C” and a peripheral circuit region “P”. The first semiconductor substrate 100 may be, for example, a silicon substrate.

A first cell isolation layer 102C is formed at the first semiconductor substrate 100 in the cell array region “C” to define a first cell active region 103C. At the first semiconductor substrate 100 in the cell array region “C”, first cell conductive regions 123S, 123, and 123D are formed between first cell gate patterns 120S, 120W, and 120G on the first cell active region 103C and first cell gate pattern 120S, 120W, and 120G, respectively. An impurity region between a first string selection line 120S and the first cell isolation layer 102C may serve as a first drain region 123D, and an impurity region between the first cell isolation layer 102C and a first ground selection line 120G may serve as a first common source region.

The first cell gate patterns 120S, 120W, and 120G may include a first wordline 120W, a first string selection line 120S, and a first ground selection line 120G which cross the first cell active region 103C and the first cell isolation layer 102C. Each of the first wordline 120W, the first string selection line 120S, and the first ground selection line 120G may include a first gate insulating pattern 104, a first floating gate pattern 106, a first gate interlayer dielectric 108, and a first control gate pattern 110 which are stacked in the order named. The first floating gate pattern 106 and the first control gate pattern 110 of the first string selection line 120S and the first floating gate pattern 106 and the first control gate pattern 110 of the first ground selection line 120G are electrically connected through a butting contact.

A peripheral isolation layer 102P is formed at the first semiconductor substrate 100 in the peripheral circuit region “P” to define a peripheral active region 103P. A peripheral gate pattern 120P is formed on the peripheral active region 103P. A peripheral conductive region 133 is formed at opposite sides adjacent to the peripheral gate pattern 120P.

The peripheral gate pattern 120P may include a first gate insulating pattern 104, a first floating gate pattern 106, a first gate interlayer dielectric pattern 108, and a first control gate pattern 110 which are stacked in the order named. The first floating gate pattern 106 and the first control gate pattern 110 of the peripheral gate pattern 120P are electrically connected through a butting contact.

Referring to FIG. 2B, a first interlayer dielectric 140 is formed to cover the first cell gate patterns 120S, 120W, and 120G and the peripheral gate pattern 120P. A second semiconductor substrate 200 may be stacked on the first interlayer dielectric 140. The second semiconductor substrate 200 is different from the first semiconductor substrate 100. That is, the second semiconductor substrate 200 may be of the same kind as the first semiconductor substrate 100, e.g., a silicon substrate including the small amount of impurities. After depositing a polysilicon layer on the first interlayer dielectric 140 in the cell array region “C” and the peripheral circuit region “P”, a second semiconductor substrate 200 of single-crystalline silicon may be formed by means of epitaxial growth process of the polysilicon layer.

Alternatively, a semiconductor substrate 200 may be provided which includes a cell array region “C” and a peripheral circuit region “P” formed from different materials. For example, after a polysilicon layer is deposited only on a first interlayer dielectric 140 in a cell array region “C”, a single-crystalline layer may be formed by means of epitaxial growth of the polysilicon layer. After forming the single-crystalline silicon layer, a polysilicon layer may be deposited only on a first interlayer dielectric 140 in a peripheral circuit region “P”.

Referring to FIG. 2C, while the second semiconductor substrate 200 in the peripheral circuit region “P” is covered with a first encapsulation layer 201a, a second cell isolation layer 202C may be formed in the cell array region “C” to define a second cell active region 203C. Simultaneously, second cell conductive regions 223S, 223, and 223D may be formed at opposite sides of second cell gate patterns 220S, 220W, and 220G on the second cell active region 203C and second cell gate patterns 220S, 220W, and 220G, respectively. The first encapsulation layer 201a may be, for example, a silicon oxide layer. The second cell gate patterns 220S, 220W, and 220G may include a second wordline 220W, a second string selection line 220S, and a second ground selection line 220G which cross the second cell active region 203C and the second cell isolation layer 202C. Each of the second wordline 220W, the second string selection line 220S, and the second ground selection line 220G may include a second gate insulating pattern 204, a second floating gate pattern 206, a second gate interlayer dielectric pattern 206, and a second control gate pattern 210 which are stacked in the order named. The second floating gate pattern 206 and the second control gate pattern 210 of the second string selection line 220S and the second floating gate pattern 206 and the second control gate pattern 210 of the second ground selection line 220G are electrically connected through a butting contact. The first encapsulation layer 201a is removed.

Referring to FIG. 2D, while the second cell gate patterns 220S, 220W, and 220G formed on the second substrate 200 in the cell array region “C” are covered with a second encapsulation layer 201b, the second semiconductor substrate 200 may be patterned to form a cell semiconductor pattern 200C in the cell array region “C” and a peripheral semiconductor pattern 200P in the peripheral circuit region “P”. The second encapsulation layer 201b may be, for example, a silicon oxide layer. The second encapsulation layer 201b may be removed.

The peripheral semiconductor pattern 200P may have substantially the same thickness as the cell semiconductor pattern 200C. The peripheral semiconductor pattern 200P may have a smaller width than the cell semiconductor pattern 200C. The peripheral semiconductor pattern 200P may be, for example, a single-crystalline silicon pattern including a small amount of impurities (e.g., the same as the cell semiconductor pattern 200C). Alternatively, the peripheral semiconductor pattern 200P may be a polysilicon pattern including the small amount of impurities or an impurity-free (un-doped) polysilicon pattern.

According to the illustrated first embodiment of the invention, a resistor may be fabricated from the peripheral semiconductor pattern 200P—which is essentially used as a resist material. The peripheral semiconductor pattern 200P may be formed on the peripheral gate pattern 120P in the peripheral circuit region “P” in parallel with the cell semiconductor pattern 200C. Thus, the overall chip size of the resulting semiconductor device including a resistor may be reduced as compared with conventional devices wherein a resist material is disposed in a special resist region or on the peripheral isolation layer 202P of the peripheral circuit region “P”.

According to the illustrated first embodiment of the invention, the peripheral semiconductor pattern 200P may be used to fabricate or implement a resistor having a relatively high resistance because the constituent material of the peripheral semiconductor pattern 200P includes little or no additionally doped impurities. Thus, a semiconductor device having a stable resistance dispersion may be provided and the overall fabrication costs for the resulting semiconductor device may be reduced.

Referring to FIG. 2E, a second interlayer dielectric 240 is formed to cover the second cell gate patterns 220S, 220W, and 220G and the peripheral semiconductor pattern 200P. A source line contact 250 is formed through the second interlayer dielectric 240, the cell semiconductor pattern 200C, and the first interlayer dielectric 140 to electrically connect the second common source region 223S to the first common source region 123S.

Referring to FIG. 2F, a third interlayer dielectric 242 is formed on the second interlayer dielectric 240 in the cell array region “C” and the peripheral circuit region “P”. Resist contacts 260 are formed through the third and second interlayer dielectrics 242 and 240 in the peripheral circuit region “P” to be electrically connected to the peripheral circuit pattern 200P. Resist interconnections 262 are formed on the third interlayer dielectric 242 to be electrically connected to resist contacts 260.

A bitline contact 254 may be formed through the third and second interlayer dielectrics 242 and 240, the cell semiconductor pattern 200C, and the first interlayer dielectric 140 in the cell array region “C” to be electrically connected to a second drain region 223D and a first drain region 123D. A bitline 254 may be formed on the third interlayer dielectric 242 to be electrically connected to the bitline contact 252.

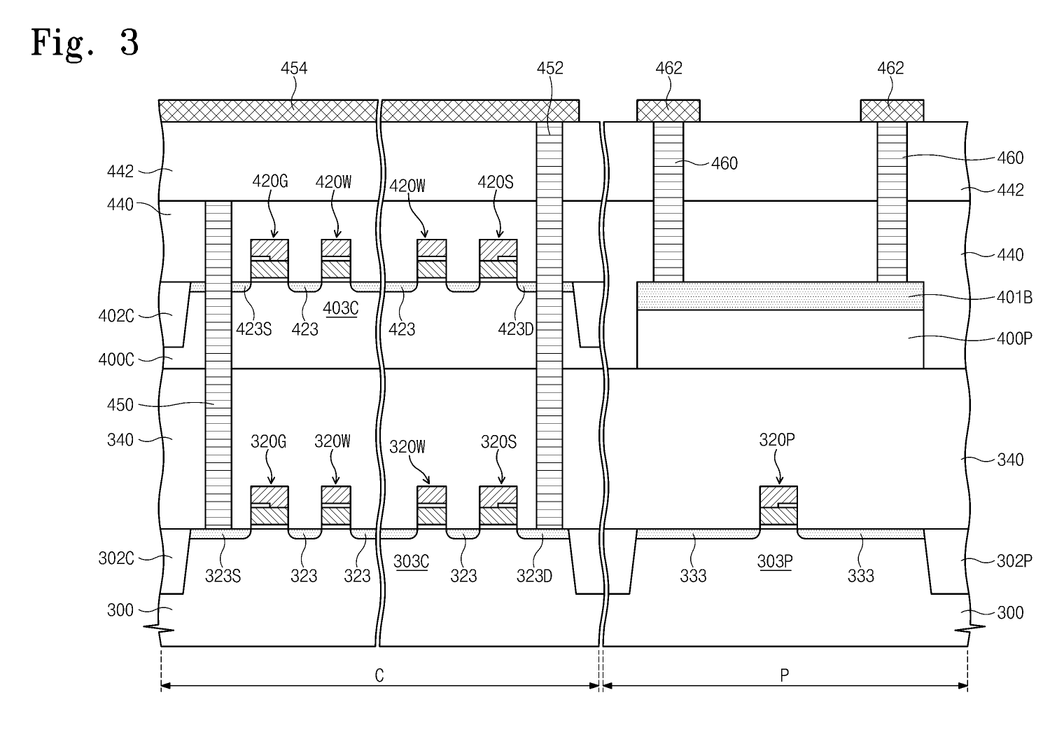

FIG. 3 is a cross-sectional view of a semiconductor device according to a second embodiment of the invention. Since this exemplary semiconductor device is similar to that of the illustrated first embodiment of the invention only non-duplicate elements will be described. It should be noted that a numbering convention of 4XX and 3XX is now used in place of 2XX and 1XX to indicate similar corresponding elements.

Referring to FIG. 3, various elements and structures are formed in a cell region “C” similar to those described in FIG. 1.

A peripheral isolation layer 302P is disposed in a semiconductor substrate 300 in a peripheral circuit region “P” to define a peripheral active region 303P. A peripheral gate pattern 320P is disposed on the peripheral active region 303P, and a peripheral conductive region 333 may be disposed in the semiconductor substrate 100 adjacent to opposite sides of the peripheral gate pattern 320P.

A peripheral semiconductor pattern 400P is disposed on a first interlayer dielectric 340 in the peripheral circuit region “P”. The peripheral semiconductor pattern 400P may have the same thickness as a cell semiconductor pattern 400C and have a smaller width than the cell semiconductor pattern 400C. The peripheral semiconductor pattern 400P may be used as a resist material. The peripheral semiconductor pattern 400P may be formed of the same/different material as/from the cell semiconductor pattern 400C. The peripheral semiconductor pattern 400P may be, for example, a single-crystalline silicon pattern or a polysilicon pattern.

Unlike the illustrated first embodiment of the invention, a resistor may be formed from materials implementing the peripheral semiconductor pattern 400P and a layer 401B of impurities (hereinafter referred to as “impurity layer 401B”) implanted in the upper surface of the peripheral semiconductor pattern 400P. The impurity layer 401B will typically have a lesser thickness than the peripheral semiconductor pattern 400P. In case the peripheral semiconductor pattern 400P already includes a small amount of first-type impurities, the impurity layer 401B may include a greater amount of first and/or second-type impurities than the initial small amount of first-type impurities. In certain embodiments of the invention, said first-type impurities are assumed to be P-type impurities, and said second-type impurities are assumed to be N-type impurities.

According to the illustrated second embodiment of the invention, the impurity layer 401B is provided in an upper portion of the peripheral semiconductor pattern 400P. In this manner, the constituent resistance of the resist material may be adjusted by varying the concentration of doped impurities and/or the thickness of the impurity layer 401B. For example, the impurity layer 401B may be formed to a greater depth than the first cell conductive regions 423S, 423, and 423D to provide a reduced resistance relative to the first cell conductive regions 423S, 423, and 423D. Alternatively, the impurity layer 401B may be formed to a similar depth as the first cell conductive regions 423S, 423, and 423D to provide a similar resistance as the first cell conductive regions 423S, 423, and 423D. Moreover, the peripheral semiconductor pattern 400P may include an impurity layer having the same thickness as the peripheral semiconductor pattern 400P to provide considerably low resistance.

Resist contacts 460 are electrically connected to the peripheral semiconductor pattern 400P through the third and second interlayer dielectrics 442 and 440. Resist interconnections 462 are disposed on the third interlayer dielectric 442 to be electrically connected to the resist contacts 460.

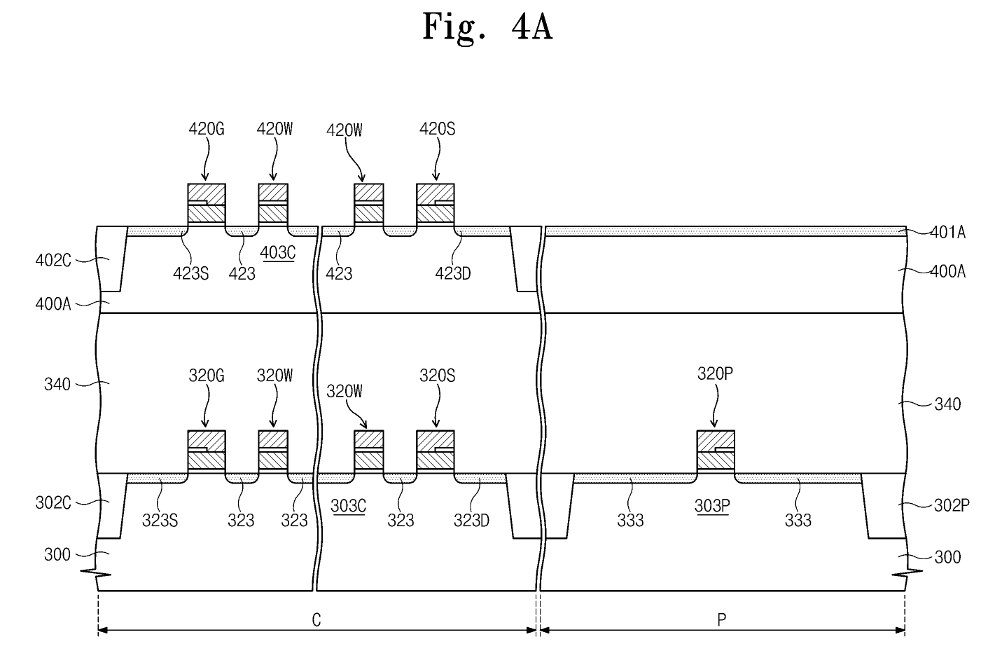

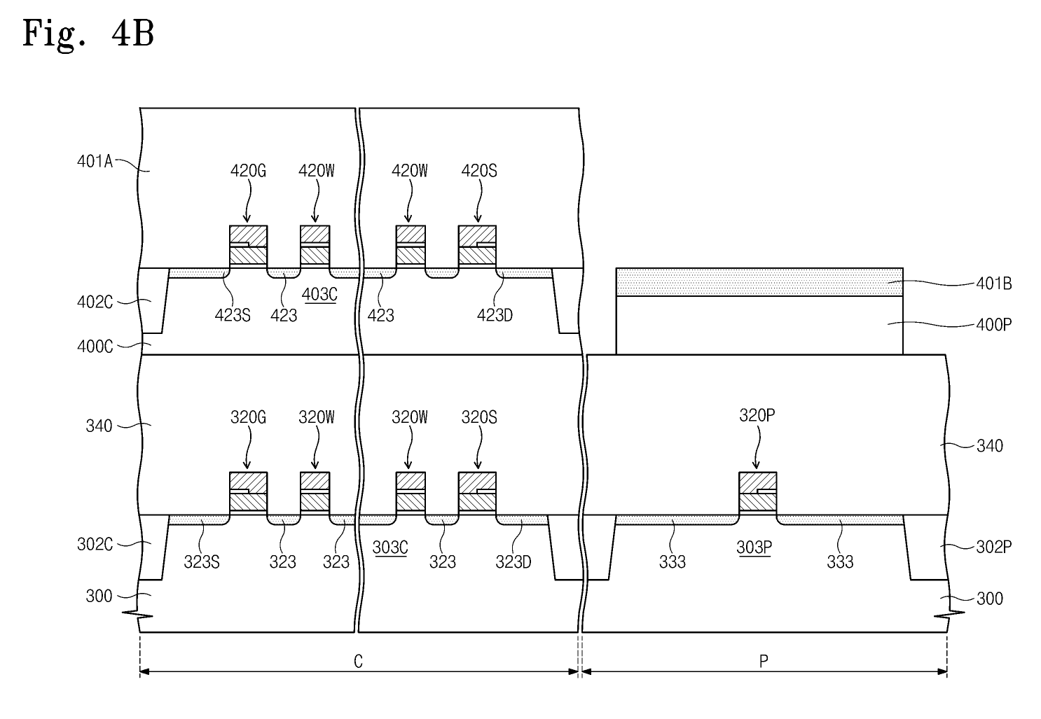

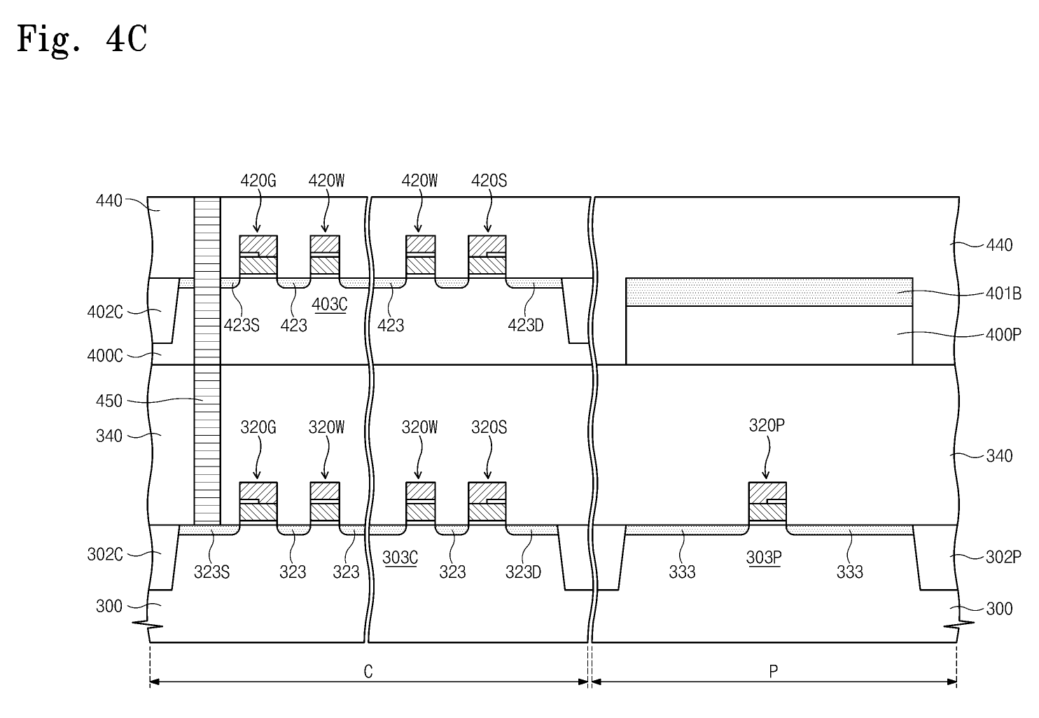

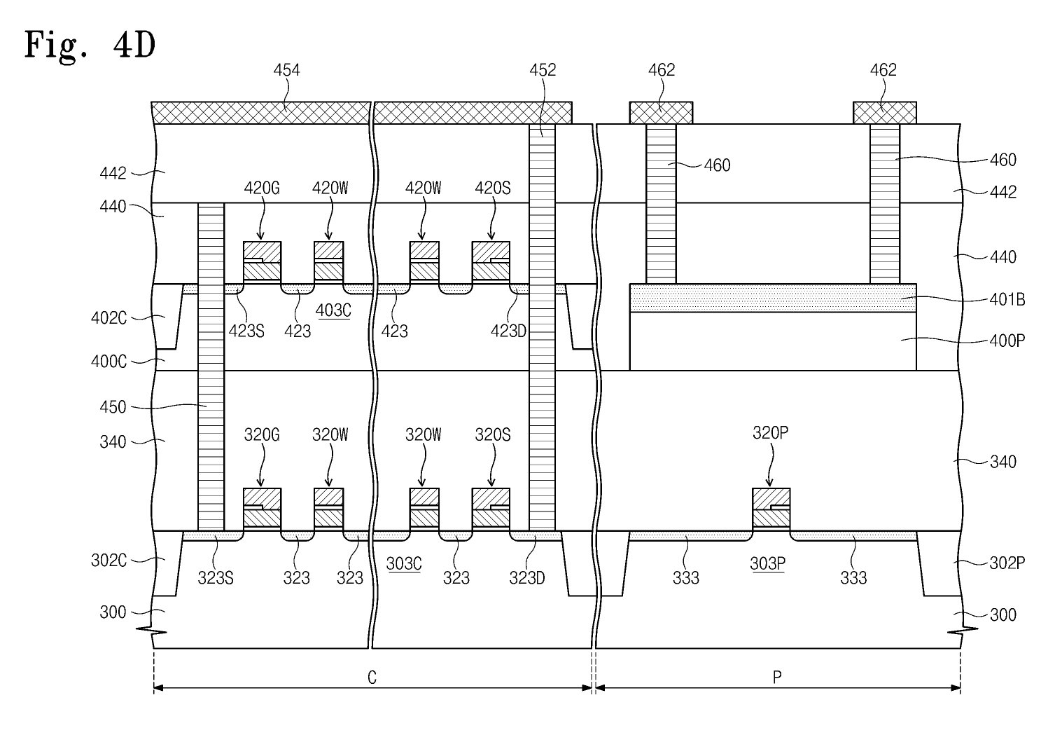

FIGS. 4A through 4D are cross-sectional views illustrating a method of fabricating a semiconductor device according to the illustrated second embodiment of the present invention. Since this fabrication method is similar to that of the illustrated first embodiment only non-duplicate steps and characteristics will be described.

Referring to FIG. 4A, as well as FIGS. 2A and 2B, a second semiconductor substrate 400A may be stacked on a first interlayer dielectric 340. It is noted that the second semiconductor substrate 400A may be different from a first semiconductor substrate 300. The second semiconductor substrate 400A may be a substrate of the same kind as the first semiconductor substrate 300 and may be a silicon substrate including the small amount of impurities. Alternatively, a second semiconductor substrate 400A may be formed of two different materials in a cell array region “C” and a peripheral circuit region “P”, respectively. For example, after depositing a polysilicon layer only on the first interlayer dielectric 340 in the cell array region “C”, a single-crystalline silicon layer may be formed by epitaxially growing the polysilicon layer. After forming the single-crystalline layer, a polysilicon layer may be deposited only on the first interlayer dielectric 340 in the peripheral circuit region “P”.

While the second semiconductor substrate 400A in the peripheral circuit region “P” is covered with a first encapsulation layer (not shown), a second cell isolation layer 402C may be formed on the second semiconductor substrate 400A in the cell array region “C” to define a second cell active region 403C. Simultaneously, second cell conductive regions 423S, 423, and 423D may be formed at opposite sides of second cell gate patterns 420S, 420W, and 420G on the second cell active region 403C and second cell gate patterns 420S, 420W, and 420G, respectively. The second cell gate patterns 420S, 420W, and 420G may include second wordlines 420W, a second string selection line 420S, and a second ground selection line 220G which cross the second cell active region 403C and the second cell isolation layer 402C.

According to the illustrated second embodiment of the invention, a first impurity layer 401A is formed in an upper portion of the second semiconductor substrate 400A in the peripheral circuit region “P”. This may be done simultaneously with the formation of the second cell conductive regions 423S, 423, and 423D, or as a separate fabrication step. In the illustrated embodiment, the first impurity layer 401A has the same depth as the second cell conductive regions 423S, 423, and 423D in order to provide a similar resistance as the second cell conductive regions 423S, 423, and 423D.

Referring to FIG. 4B, while the second semiconductor substrate 400A in the cell array region “C” is covered with a second encapsulation layer 401A, the second semiconductor substrate 400A in the peripheral circuit region “P” may be patterned to form a cell semiconductor pattern 400C in the cell array region “C” and a peripheral semiconductor pattern 400P in the peripheral circuit region “P”. The peripheral semiconductor pattern 400P may have a smaller width than the cell semiconductor pattern 400C. The peripheral semiconductor pattern 400P may have the same thickness as the cell semiconductor pattern 400C. The peripheral semiconductor pattern 400P may be formed of the same material as the cell semiconductor pattern 400C or a different material to the cell semiconductor pattern 400C. The peripheral semiconductor pattern 400P may be, for example, a single-crystalline silicon pattern or polysilicon pattern. The peripheral semiconductor pattern 400P may be used as a resist material.

Before or after patterning the second semiconductor substrate 400A in the peripheral circuit region “P”, an ion implanting process may be carried out to form a second impurity region 401B at the peripheral semiconductor pattern 400P. The second impurity region 401B extends from the first impurity layer 401A. In case the peripheral semiconductor pattern 400P already includes the small amount of first-type impurities, the impurity layer 401B may include a greater amount of first or second-type impurities than the small amount of first-type impurities. In case the first-type impurities are P-type impurities, the second-type impurities may be N-type impurities.

According to the illustrated second embodiment of the invention, an impurity layer is provided in an upper portion of the peripheral semiconductor pattern 400P. In this manner, a constituent resistance of the resist material may be adjusted by varying the thickness (e.g., the implantation depth) and/or the impurity concentration of the impurity layer 401B.

Referring to FIG. 4C, a second interlayer dielectric 440 is formed to cover the second cell gate patterns 420G, 420W, and 420S and the peripheral semiconductor pattern 400P. A source line contact 450 is formed through the second interlayer dielectric 440, the cell semiconductor pattern 400C, and the first interlayer dielectric 340 to electrically connect the second common source region 423S to the first common source region 323S.

Referring to FIG. 4D, a third interlayer dielectric 442 is formed on the second interlayer dielectric 440 including the source line contact 450. Resist contacts 460 are formed through the third and second interlayer dielectrics 442 and 440 in the peripheral circuit region “P” to be electrically connected to the peripheral semiconductor pattern 400P. Resist interconnections 462 may be formed on the third interlayer dielectric 442 to be electrically connected to the resist contacts 460.

A bitline contact 452 may be formed through the third and second interlayer dielectrics 442 and 440, the cell semiconductor pattern 400, and the first interlayer dielectric 340 in the cell array region “C” to be electrically connected to a second drain region 423D and a first drain region 323D. A bitline 454 may be formed on the third interlayer dielectric 442 to be electrically connected to the bitline contact 452.

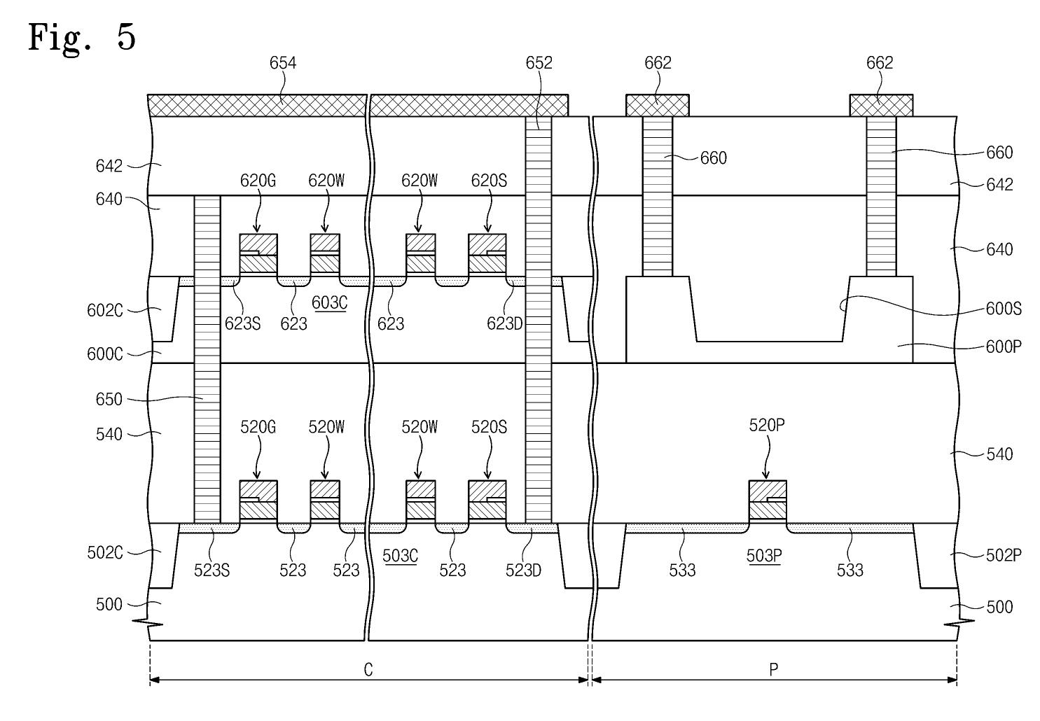

FIG. 5 is a cross-sectional view of a semiconductor device according to a third embodiment of the invention. Since this semiconductor device is similar to the illustrated first and second embodiments of the invention, only non-duplicate elements will be described. A similar numbering convention as between illustrated embodiments is again noted.

Referring to FIG. 5, the structures formed in a cell region “C” are similar to those described in FIG. 1.

A peripheral isolation layer 502P is disposed on a semiconductor substrate 500 in a peripheral circuit region “P” to define a peripheral active region 503P. A peripheral gate pattern 520P is disposed on the peripheral active region 503P, and a peripheral conductive region 533 may be disposed in the semiconductor substrate 100 adjacent to opposite sides of the peripheral gate pattern 520P.

A peripheral semiconductor pattern 600P is disposed on a first interlayer dielectric 540 in the peripheral circuit region “P”. The peripheral semiconductor pattern 600P may be formed at a similar or different level as the cell semiconductor pattern 600C. The peripheral semiconductor pattern 600P may be a single-crystalline silicon pattern or a polysilicon pattern. A resistor is implemented using the peripheral semiconductor pattern 600P as modified in its constituent resistive characteristics by a recessed region 600S formed in the peripheral semiconductor pattern 600P.

Unlike with the peripheral semiconductor patterns 200P of FIGS. 1 and 400P of FIG. 3, the peripheral semiconductor pattern 600P includes the recessed region 600S. For this reason, the peripheral semiconductor pattern 600P according to the illustrated third embodiment of the invention may exhibit a higher surface resistance than the formerly illustrated first and second embodiments. In certain related embodiments, and similar to the illustrated second embodiment of the invention, an impurity layer may be formed in an upper portion of the peripheral semiconductor pattern 600P to adjust its constituent resistive properties. This may be done either before or after the formation of recessed region 600S.

A second interlayer dielectric 640 covers second cell gate patterns 620G, 620W, and 620S and the peripheral semiconductor pattern 600P. A source line contact 650 electrically connects a second common source region 623S to a first common source region 523S through the second interlayer dielectric 640, the cell semiconductor pattern 600C, and the first interlayer dielectric 540. A third interlayer dielectric 642 is disposed on the second interlayer dielectric 640 including the source line contact 650.

Resist contacts 660 are electrically connected to the peripheral semiconductor pattern 600P through the third and second interlayer dielectrics 642 and 640. Resist interconnections 662 are disposed on the third interlayer dielectric 642 to be electrically connected to the resist contacts 660. A bitline contact 652 may be electrically connected to a second drain region 623D and a first drain region 523d through the third and second interlayer dielectrics 642 and 640, the cell semiconductor pattern 600C, and the first interlayer dielectric 540. A bitline 654 is disposed on the second interlayer dielectric 640 to be electrically connected to the bitline contact 652.

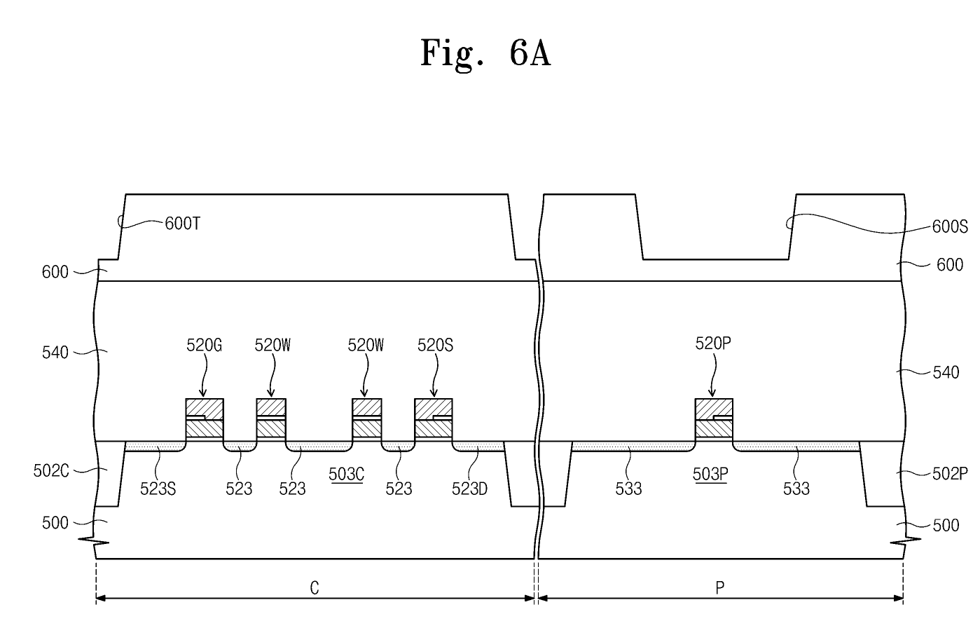

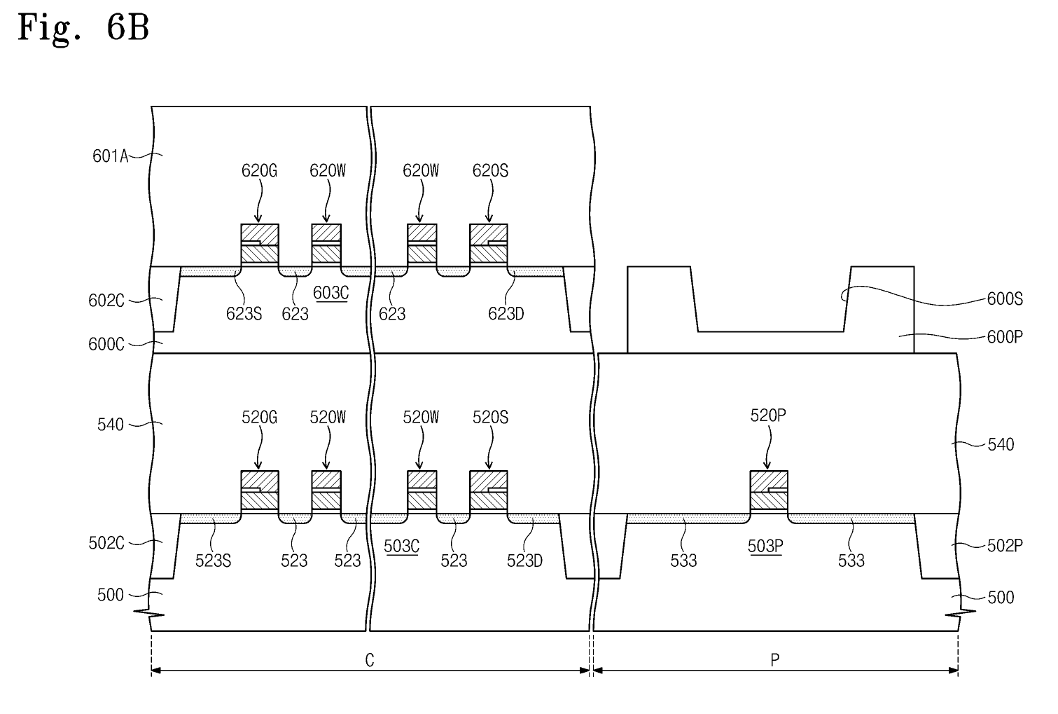

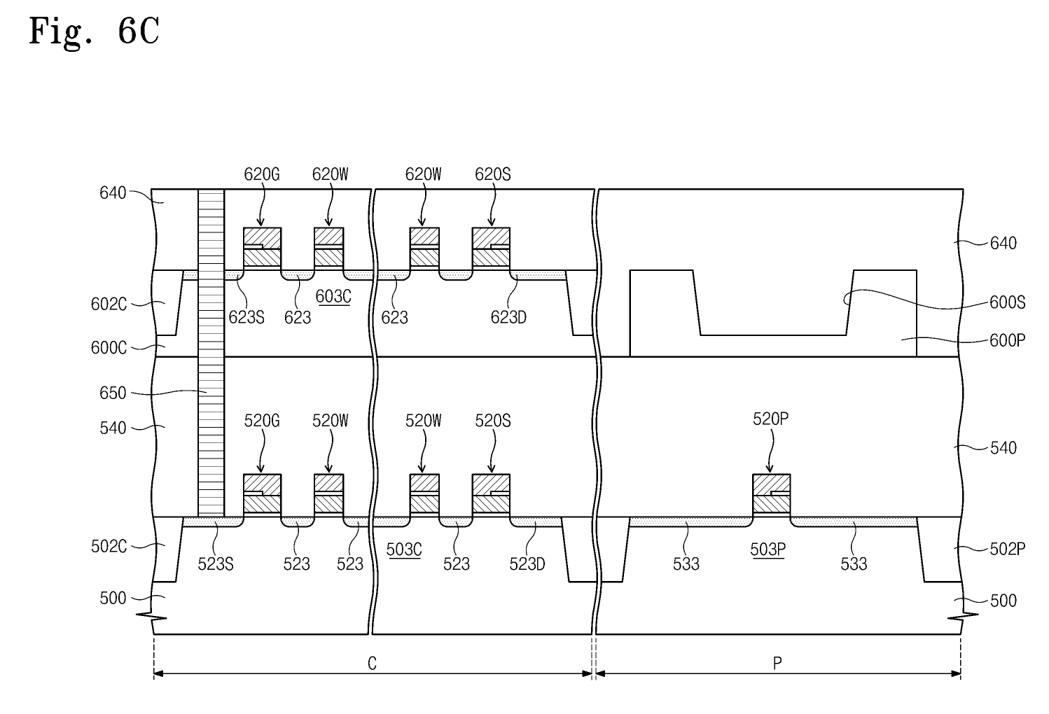

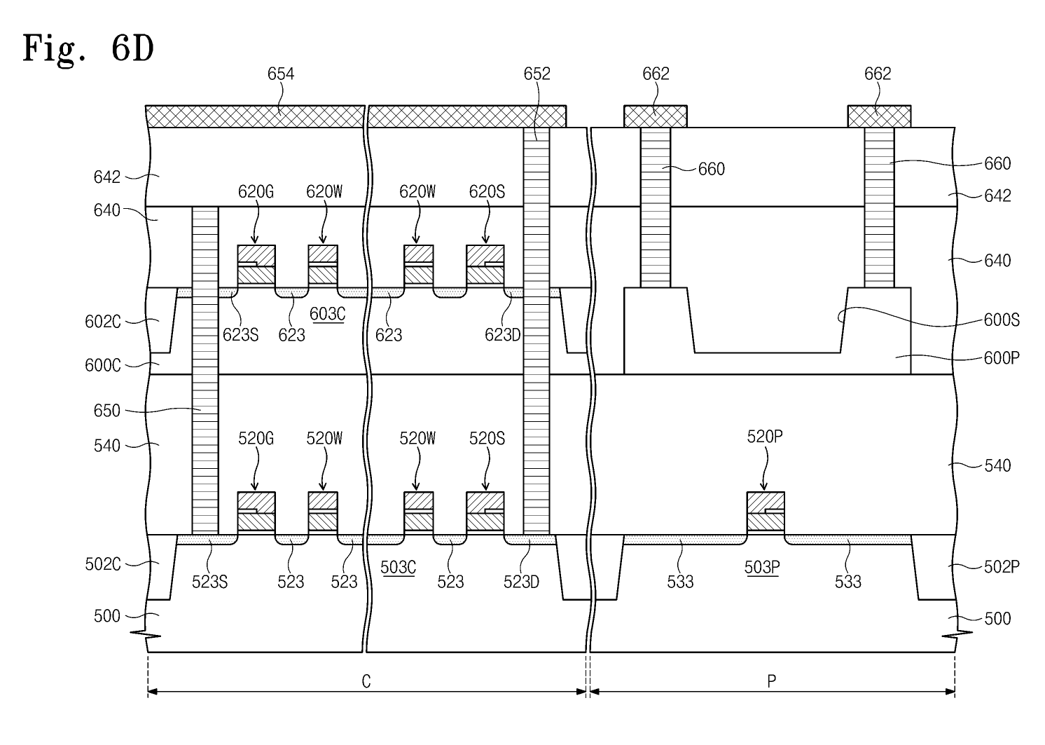

FIGS. 6A through 6D are cross-sectional views illustrating a method of fabricating a semiconductor device according to the illustrated third embodiment of the invention. Since this method is similar to that of the illustrated first and second embodiments, only non-duplicate method steps and characteristics will be described.

Referring to FIG. 6A, as described in FIGS. 2A through 2B, a second semiconductor substrate 600 may be stacked on a first interlayer dielectric 540. The second semiconductor substrate 600 may be a substrate of the same kind as the first semiconductor substrate 500 and may be a silicon substrate including the small amount of impurities. Alternatively, a second semiconductor substrate 600 may be formed of two different materials in a cell array region “C” and a peripheral circuit region “P”, respectively. For example, after depositing a polysilicon layer only on the first interlayer dielectric 540 in the cell array region “C”, a single-crystalline silicon layer may be formed by epitaxially growing the polysilicon layer. After forming the single-crystalline layer, a polysilicon layer may be deposited only on the first interlayer dielectric 540 in the peripheral circuit region “P”.

A recessed region 600S is formed in the second semiconductor substrate 600 in the peripheral circuit region “P”. In certain embodiments of the invention, the fabrication step used to form recessed region 600S may also be used to simultaneously form a trench 600T in the second semiconductor substrate 600 in the cell array region “C”. The recessed region 600S may therefore be formed in the second semiconductor substrate 600 to have the same depth as the trenches 600T. The trench 600T is thereafter filled to form a second cell isolation layer 602C of FIG. 6B.

Referring to FIG. 6B, while a second semiconductor substrate (600 of FIG. 6A) in the peripheral circuit region “P” is covered with a first encapsulation layer (not shown), a second cell isolation layer 602C may be formed to define a second cell active region 603C by filling the trenches (600T of FIG. 6A) with an insulating layer. Simultaneously, second cell gate patterns 620G, 620W, and 620S may be formed on the second cell active region 603C and second cell conductive regions 623S, 623, and 623D may be formed between the second cell gate patterns 620G, 620W, and 620S. The first encapsulation layer may be, for example, a silicon oxide layer. The first encapsulation is removed.

While a second semiconductor substrate (600 of FIG. 6A) in the cell array region “C” is covered with a second encapsulation layer 601A, the second semiconductor substrate 600 including the recessed region 600S may be patterned to form a cell semiconductor pattern 600C in the cell array region “C” and a peripheral semiconductor pattern 600P in the peripheral circuit region “P”. A resistor may include the peripheral semiconductor pattern 600P used as a resist material and the recessed region 600S on the peripheral semiconductor pattern 600P.

Since the peripheral semiconductor pattern 600P according to the third embodiment includes the recessed region 600S, it may have higher surface resistance than the peripheral semiconductor patterns (200P of FIGS. 1 and 400P of FIG. 3) according to the first and second embodiments. Similar to the second embodiment, an impurity layer may be formed on the peripheral semiconductor pattern 600P and resistance of the peripheral semiconductor pattern 600P may be adjusted by adjusting the depth of the impurity layer.

Referring to FIG. 6C, a second interlayer dielectric 640 is formed to cover the second cell gate patterns 620G, 620W, and 620S and the peripheral semiconductor pattern 600P. A source line contact 650 is formed through the second interlayer dielectric 640, the cell semiconductor pattern 600C, and the first interlayer dielectric 540 to electrically connect the second common source region 623S to the first common source region 523S.

Referring to FIG. 6D, a third interlayer dielectric 642 is formed on the second interlayer dielectric 640 including the source line contact 650. Resist contacts 660 are formed through the third and second interlayer dielectrics 642 and 640 in the peripheral circuit region “P” to be electrically connected to the peripheral semiconductor pattern 600P. Resist interconnections 662 may be formed on the third interlayer dielectric 642 to be electrically connected to the resist contacts 660.

A bitline contact 652 may be formed through the third and second interlayer dielectric 642 and 640, the cell semiconductor pattern 600C, and the first interlayer dielectric 540 in the cell array region “C” to be electrically connected to a second drain region 623D and a first drain region 523D. A bitline 654 may be formed on the third interlayer dielectric 642 to be electrically connected to the bitline contact 652.

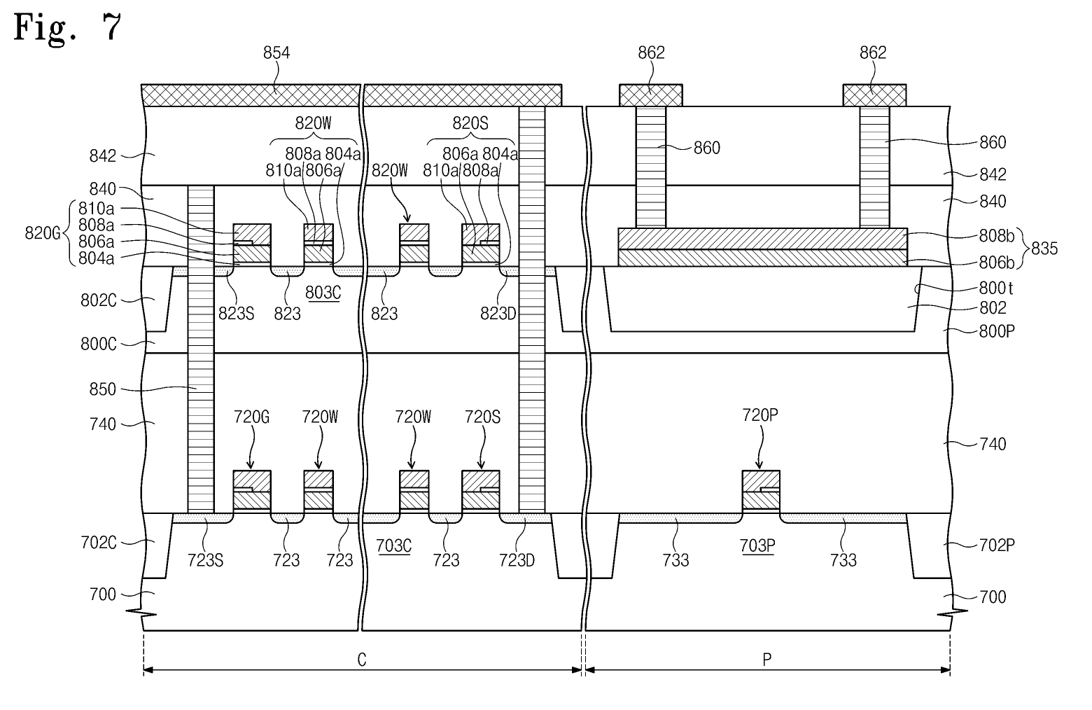

FIG. 7 is a cross-sectional view of a semiconductor device according to a forth embodiment of the invention. Since this semiconductor device is similar to that of the illustrated first, second, and third embodiments, only non-duplicate elements and characteristics will be described.

Referring to FIG. 7, the structures formed in a cell region “C” are similar to those described in FIG. 1.

A peripheral isolation layer 702P is disposed on a semiconductor substrate 700 to define a peripheral active region 703P. A peripheral gate pattern 720P is disposed on the peripheral active region 703P, and a peripheral conductive region 733 may be disposed in the semiconductor substrate 100 adjacent to opposite sides of the peripheral gate pattern 720P. A first interlayer dielectric 740 is disposed to cover the peripheral gate pattern 720P.

A peripheral semiconductor pattern 800P is disposed on the first interlayer dielectric 740 in the peripheral circuit region “P”. The peripheral semiconductor pattern 800P may be made of the same material as a cell semiconductor pattern 800C or a different material to the cell semiconductor pattern 800C. The peripheral semiconductor pattern 800P may be, for example, a single-crystalline silicon pattern or a polysilicon pattern. The peripheral semiconductor pattern 800P may include a peripheral trench 800t. A filling insulator 802 is disposed to fill the peripheral trench 800t. A resist conductive pattern 835 is disposed on the filling insulator 802. The resist conductive pattern 835 may include a first conductive pattern 806b and a second conductive pattern 808b stacked thereon. Alternatively, the resist conductive pattern 835 may include only the first conductive pattern 806b. The first conductive pattern 806b may include the same material as a floating gate pattern 806a included in second cell gate patterns 820G, 820W, and 820S. The first conductive pattern 806b may include, for example, polysilicon. The second conductive pattern 808b may include the same material as a control gate pattern 810a included in the second cell gate patterns 820G, 820W, and 820S. The second conductive pattern 808b may include, for example, polysilicon. That is, the resist conductive pattern 835 may be made of the same material as one selected from the group consisting of a floating gate pattern 806a, a control gate pattern 810a, and combination thereof. According to the fourth embodiment, a resistor may include the peripheral semiconductor pattern 800P, the filling insulator 802, and the resist conductive pattern 835.

Unlike the peripheral semiconductor patterns 200P of FIG. 1, 400P of FIG. 3, and 600P of FIG. 5, the fourth illustrated embodiment of the invention uses a conductive resist pattern 835 as a resist material. The resist conductive pattern 835 may extend along a top surface of the filling insulator 802 to obtain a desired high resistance.

A second interlayer dielectric 840 is disposed to cover the resist conductive pattern 835. Resist contacts are disposed through the third and second interlayer dielectrics 842 and 840 to be electrically connected to the resist conductive pattern 835. Resist interconnections 842 are disposed on the third interlayer dielectric 842 to be electrically connected to the resist contacts 860.

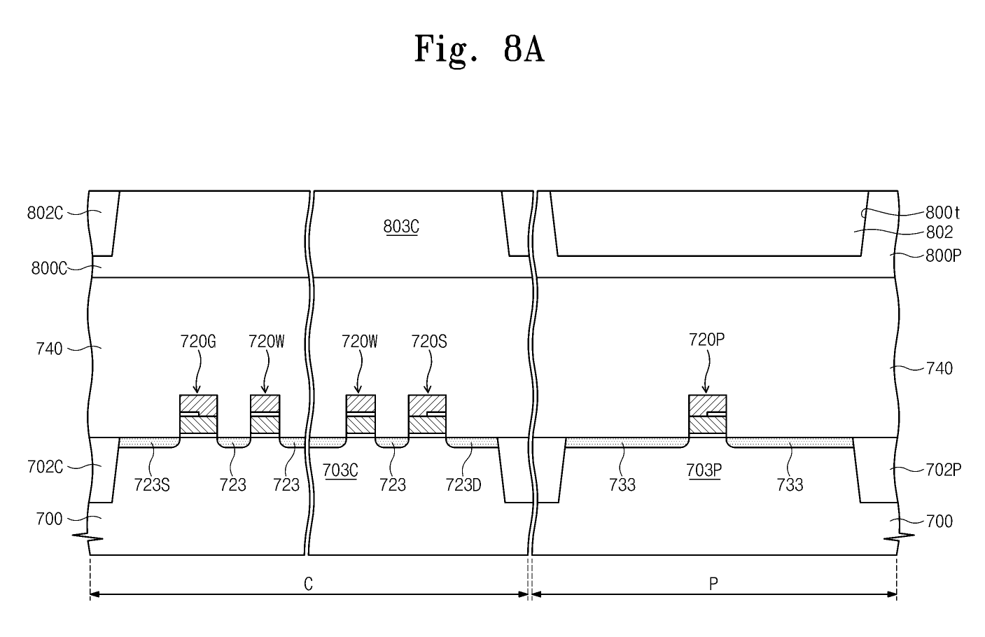

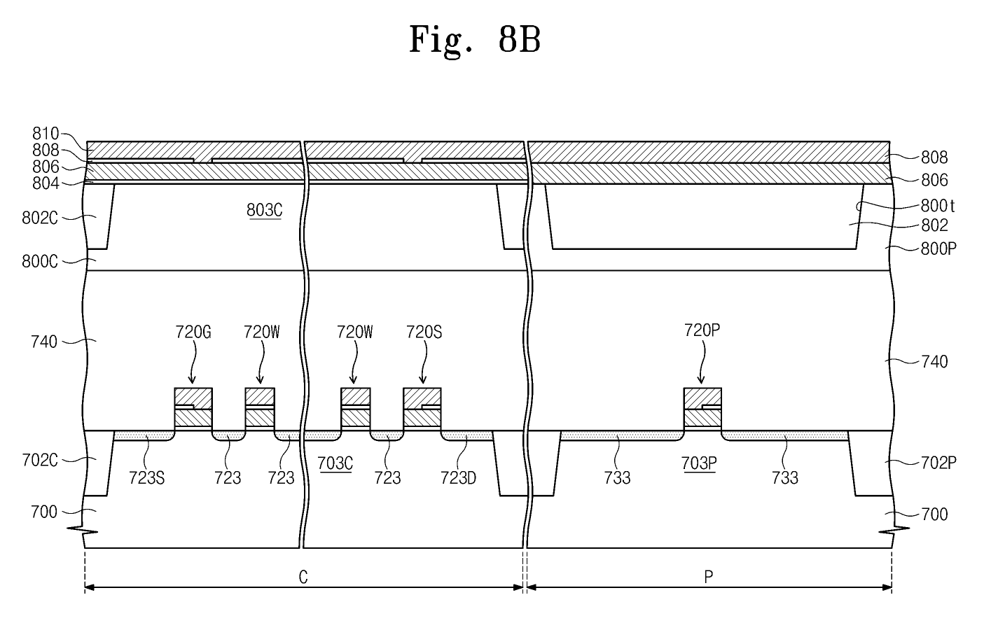

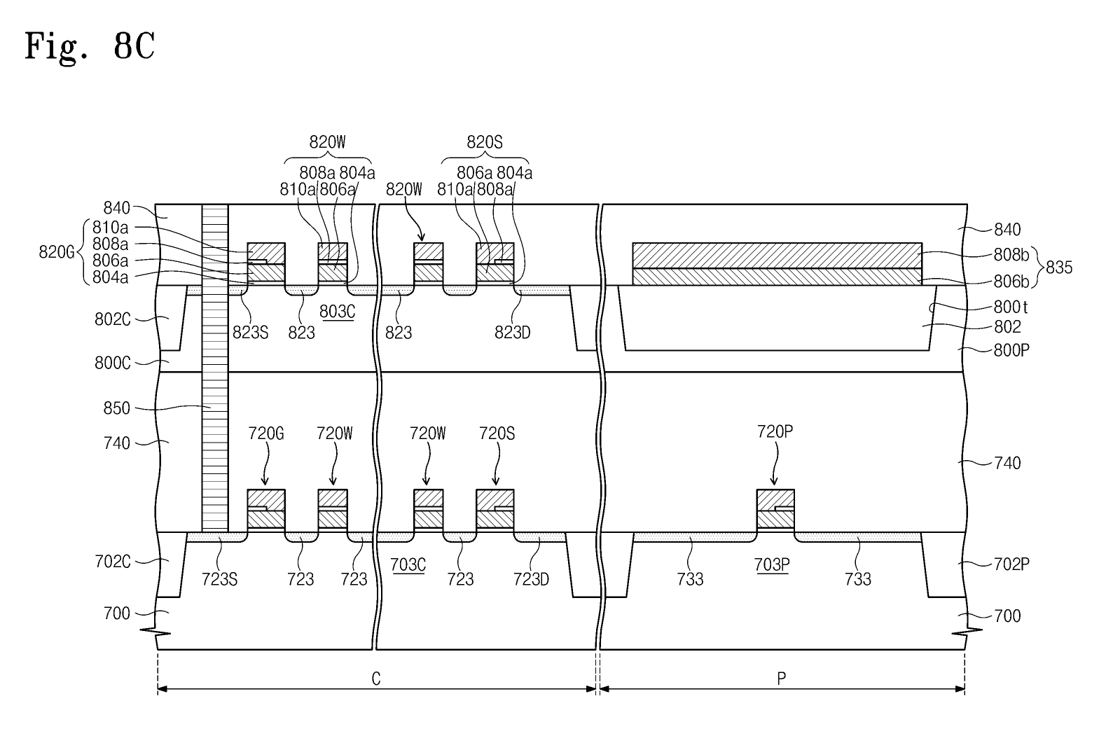

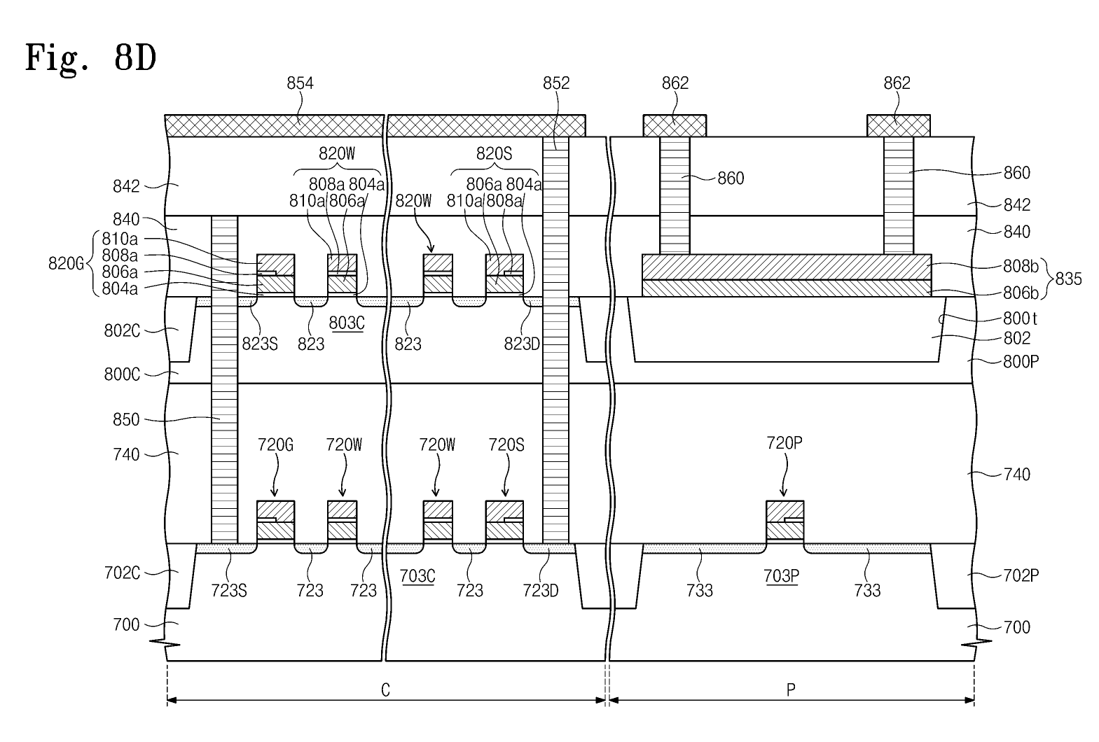

FIGS. 8A through 8D are cross-sectional views illustrating a method of fabricating a semiconductor device according to the illustrated fourth embodiment of the invention.

Referring to FIG. 8A, as described in FIGS. 2A and 2B, a second semiconductor substrate may be stacked on a first interlayer dielectric 740. It is noted that the second semiconductor substrate may be different from a first semiconductor substrate 700. The second semiconductor substrate may be a substrate of the same kind as the first semiconductor substrate 700. That is, the second semiconductor substrate is, for example, a silicon substrate. Alternatively, a second semiconductor substrate may be formed, including a cell array region “C” and a peripheral circuit region “P” which are formed of different materials. For example, after depositing a polysilicon layer only on a first interlayer dielectric 740 in the cell array region “C”, a singe-crystalline silicon layer may be formed by epitaxially growing the polysilicon layer. After forming the single-crystalline silicon layer, a polysilicon layer may be deposited only on a first interlayer dielectric 740 in the peripheral circuit region “P”.

The second semiconductor substrate in the cell array region “C” and the peripheral circuit region “P” may be patterned to form a cell semiconductor pattern 800C with isolation trenches in the cell array region “C” and form a peripheral semiconductor pattern 800P with a peripheral trench 800t in the peripheral circuit region “P”. The peripheral trench 800t may be formed to have the same/similar depth as/to the isolation trenches. The isolation trenches and the peripheral trench 800t may be filled with an insulating layer to form a second cell isolation layer 802C in the cell array region “C” and a filling insulator 802 in the peripheral circuit region “P”. The second cell isolation 802C defines a second cell active region 803C. That is, the peripheral trench 800t and the filling insulator 802 may be formed to fill the peripheral trench 800t by means of a process for forming the second cell isolation layer 802C in the cell array region “C”. The interlayer dielectric 802 and the second cell isolation layer 802C may include, for example, silicon oxide.

Referring to FIG. 8B, a second gate insulator 804 may be formed on the second cell active region 803C. The second gate insulator 804 may be, for example, a thermal oxide layer and not be formed on the filling insulator 802 formed of silicon oxide.

A first conductive layer 806 and a second conductive layer 808 may be sequentially formed on the peripheral semiconductor pattern 800P in the peripheral circuit region “P”. The first and second conductive layers 806 and 808 may be formed at the same time of forming a second floating gate layer 806, a second intergate dielectric 808, and a second control gate layer 810 which are sequentially stacked on the second gate insulator 804 in the peripheral circuit region “P”. That is, the first conductive layer 806 may be the second floating gate layer 806, and the second conductive layer 808 may be the second control gate layer 810. The second floating gate layer 806 and the second control gate layer 810 may each include, for example, polysilicon. The second control gate layer 810 may include a greater amount of impurities than the second floating gate layer 806. Since the second intergate dielectric 808 may be formed while the first conductive layer 806 is covered with a first encapsulation layer (not shown), it is not interposed between the first and second conductive layers 808.

Referring to FIG. 8C, the second floating gate layer 806, the second intergate dielectric 808, and the second control gate layer 810, which are sequentially stacked on the second gate insulator 804 in the peripheral circuit region “P”, are patterned to form second cell gate patterns 820G, 820W, and 820S. At the same time, the second conductive layer 808 and the first conductive layer 806 may be patterned to form a second conductive pattern 808b and a first conductive pattern 806b. The second and first conductive patterns 808b and 806b may constitute a resist conductive pattern 835. Alternatively, the resist conductive pattern 835 may include only the first conductive pattern 806b. A resistor may include the peripheral semiconductor pattern 800P, the filling insulator 802, and the resist conductive pattern 835.

Unlike the fact that the peripheral semiconductor patterns (200P of FIG. 1, 400P of FIG. 3, and 600P of FIG. 5) according to the first to third embodiments are each used as a resist material, the resist conductive pattern 835 may be used as a resist material. The resist conductive pattern 835 may extend along a top surface of the filling insulator 802 to provide high resistance.

Second cell conductive regions 823S, 823, and 823D may be formed between the second cell gate patterns 820G, 820W, and 820S. A second interlayer dielectric 840 are formed to cover the second cell gate patterns 820G, 820W, and 820S and the peripheral semiconductor pattern 800P. A source line contact 850 is formed through the second interlayer dielectric 840, the cell semiconductor pattern 800C, and the first interlayer dielectric 740 to electrically connect the second common source region 823S to the first common source region 723S.

Referring to FIG. 8D, a third interlayer dielectric 842 is formed on the second interlayer dielectric 840 including the source line contact 850. Resist contacts 860 are formed through the third and second interlayer dielectrics 842 and 840 in the peripheral circuit region “P” to be electrically connected to the resist conductive pattern 835. Resist interconnections 862 may be formed on the third interlayer dielectric 842 to be electrically connected to the resist contacts 860.

A bitline contact 852 may be formed through the third and second interlayer dielectrics 842 and 840, the cell semiconductor pattern 800C, and the first interlayer dielectric 740 in the cell array region “C” to be electrically connected to the second drain region 823D and the first drain region 723D. A bitline 854 may be formed on the third interlayer dielectric 842 to be electrically connected to the bitline contact 852.

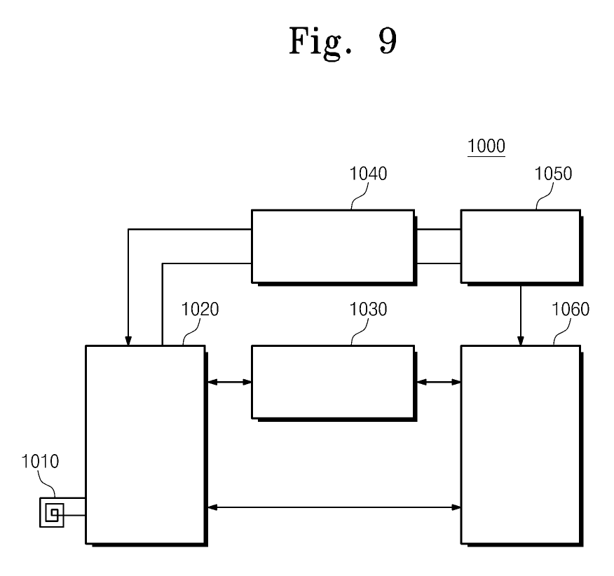

FIG. 9 is a block diagram of an electrical system incorporating a semiconductor device according to an embodiment of the present invention. The electrical system may be, for example, a mobile communication terminal 1000 including a radio frequency communication chip (RF chip) 1020, a smart card 1030, a switching circuit 1040, a battery 1050, and a controller 1060. The mobile communication terminal 1000 may include one or more semiconductor devices according to an embodiment of the invention. Therefore the mobile communication terminal 1000 has a stable resistance dispersion, allowing the operation of an electronic circuit in the mobile communication terminal 1000 to be stable. A semiconductor device according to an embodiment of the present invention may also be used to fabricate, for example, a memory chip or a logic chip. The RF chip 1020 may include, for example, a processor and a memory chip. The smart card 1030 may include a memory chip, and the controller 1060 may include a logic chip.

The RF chip 1020 performs signal transmission/reception to/from an external radio frequency identification (RFID) reader (not shown) through an antenna 1010. The RF chip 1020 transmits a signal from the smart card 1030 or the controller 1060 to the RFID reader and transmits a signal, received from the RFID reader, to the smart card 1030 or the controller 1060 through the antenna 1010. The smart card 1030 communicates with the RF chip 1020 and the controller 1060. The battery 1050 supplies a power that the mobile communication terminal 1000 requires. The controller 1060 controls the general operation of the mobile communication terminal 1000.

Electrical systems incorporating one or more semiconductor device(s) according to an embodiment of the invention may include not only the mobile communication terminal 1000 but also, for example, mobile devices such as personal digital assistants (PDAs), MP3 players, movie players, and portable game machines, desktop computers, mainframe computers, global positioning systems (GPS), PC cards, notebook computers, camcorders, and digital cameras.

Although the present invention has been described in connection with certain illustrated embodiments, it is not limited to only these embodiments. It will be apparent to those skilled in the art that various substitutions, modifications and changes may be made without departing from the scope of the invention as defined by the attached claims and their equivalents.

1. A semiconductor device comprising:
a cell array region disposed on a semiconductor substrate and comprising a first cell gate pattern, a cell semiconductor pattern disposed on the first cell gate pattern, and a second cell gate pattern disposed on the cell semiconductor pattern;
a peripheral circuit region disposed on the semiconductor substrate and comprising a peripheral gate pattern; and
a resistor disposed in the peripheral circuit region at level above the semiconductor substrate similar to that of the cell semiconductor pattern.

2. The semiconductor device of claim 1, wherein the resistor comprises a peripheral semiconductor pattern formed from the same material as the cell semiconductor pattern.

3. The semiconductor device of claim 1, wherein the resistor comprises a peripheral semiconductor pattern formed from a different material as the cell semiconductor pattern.

4. The semiconductor device of claim 2, wherein the peripheral semiconductor pattern has the same thickness as the cell semiconductor pattern.

5. The semiconductor device of claim 4, wherein the peripheral semiconductor pattern comprises a doped impurity layer formed in an upper portion of the peripheral semiconductor pattern.

6. The semiconductor device of claim 4, wherein the peripheral semiconductor pattern comprises a recessed region removed from an upper portion peripheral semiconductor pattern.

7. The semiconductor device of claim 2, wherein the resistor comprises:
a trench formed by partially removing an upper portion of the peripheral semiconductor pattern;
an insulating layer filling the trench; and
a conductive pattern disposed on the insulating layer.

8. The semiconductor device of claim 7, wherein the second cell gate pattern comprises a first gate insulator, a first floating gate layer, a first intergate dielectric, and a control gate layer sequentially stacked on the cell semiconductor pattern; and
the conductive pattern is formed from the same material as that forming at least one of the first floating gate and the control gate layer.

9-20. (canceled)
